(19) United States
(12) Patent Application Publication
(10) Pub. No.: US 2012/0080221 A1
(43) Pub. Date: Apr. 5, 2012

(54) PRINTED WIRING BOARD WITH BUILT-IN COMPONENT AND ITS MANUFACTURING METHOD

(75) Inventor: Noriaki SEKINE, Tokyo (JP)

(73) Assignee: YAMAICHI ELECTRONICS CO. LTD., Tokyo (JP)

(21) Appl. No.: 13/234,663

(22) Filed: Sep. 16, 2011

(30) Foreign Application Priority Data
Oct. 5, 2010 (JP) 2010-225493

(51) Int. Cl. H05K 1/16; H05K 3/30

(52) U.S. Cl. 174/260; 29/841

(57) ABSTRACT

A printed wiring board with components and its manufacturing method is described. An opening is formed from one main surface to another main surface of a core material. A functional element is brought into press contact with the side wall of the opening such that terminals of the functional element are exposed facing the core material's one main surface and the other main surface. A first and second interlayer dielectric layers are formed on the main surface and the other main surface, respectively, each interlayer dielectric layer having conductive bumps connected to conductive layers, with the interlayer dielectric layers filling voids between the opening and the functional element. A first terminal and a second terminal of the functional element are connected to respective first and second conductive bumps, respectively.

### CROSS-REFERENCE TO RELATED APPLICATIONS

The application claims the benefits of Japanese Patent Application No. 2010-225493 filed Oct. 5, 2010 which is hereby incorporated by reference herein its entirely.

### BACKGROUND OF THE INVENTION

1. Field of the Invention

The present invention relates to a printed wiring board with built-in component and its manufacturing method and, more particularly, to a printed wiring board with built-in component mounting electric/electronic components each composed of, e.g., a semiconductor element and its manufacturing method.

2. Description of the Related Art

Under a design trend of short, small, light, and thin of an electronic device like a mobile device, high-density mounting and short, small, light, and thin design are strongly required for a printed wiring board mounting electric/electronic components (collectively referred to as “electronic components”), and various types of multilayer wiring board are now being developed. As a result, electronic components including active elements such as a transistor, a diode, or an IC, or those such as passive elements such as a resistor or capacitor that have been surface mounted on the uppermost layer wiring circuit plane in the past are now being mounted inside a multilayer wiring board. Hereinafter, the active element and passive element are collectively referred to as “functional element”.

A related art of the printed wiring board mounting electronic component will be described below with reference to the accompanying drawings. Throughout the drawings, the same reference numerals are used to refer to the same or similar elements, and their description will be omitted partly.

A printed wiring board illustrated in FIG. 7 is an example of a multilayer wiring board in which a bypass capacitor connected to a power-supply line is incorporated (refer to, e.g., Jpn. Pat. Appln. Laid-Open Publication No. 2001-274555). In the printed wiring board illustrated in FIG. 7, a through hole 102 is formed at a predetermined position of a core material 101, and a bypass capacitor 103 is buried in the through hole 102. Both terminals 103a and 103b of the bypass capacitor 103 face first and second main surfaces of the core material 101. High melting-point solders 104 are formed on the surfaces of the both terminals 103a and 103b, respectively. Conductive plates are laminated onto the both surfaces of the core material 101 and adhered thereto by heat pressure treatment (hot press) and, at the same time, the high melting-point solders 104 are melted to solder the terminals to their corresponding conductive plates.

The adhered conductive plates are etched into circuit patterns to thereby form a first wiring circuit 105 and a second wiring circuit 106. Further, a method of applying heat/pressure treatment to a laminated structure of a known copper sheet with bump and a resin film and embedding a bump into the resin film is used to allow the first wiring circuit 105 to be electrically conductive to a third wiring circuit 109 through a first conductive bump 108 of a via penetrating a first interlayer dielectric layer 107. Similarly, the second wiring circuit 106 can be electrically conductive to a fourth wiring circuit 112 through a second conductive bump 111 penetrating a second interlayer dielectric layer 110.

In the bump embedding method, a substantially cone shaped conductive bump which is formed using a silver paste according to, e.g., a printing technique is provided at a predetermined position of a thin conductive plate, and the thin conductive plate is laminated onto the both surfaces of the core material 101 through a prepreg material followed by being subjected to hot press. By such a lay-up process, a multilayer printed wiring board is obtained.

In the hot press process of the printed wiring board, one of the conductive plates is laminated onto, e.g., the second main surface of the core material 101, and then the bypass capacitor 103 is inserted into the through hole 102. At this time, the bypass capacitor 103 is mounted so as to be supported by this conductive plate. In this state, the other one of the conductive plates is laminated onto the first main surface of the core material 101 for hot press. This is because the bypass capacitor 103 cannot be fixed in the through hole 102. Therefore, the hot press process is difficult to simplify.

Further, since soldered joint cannot be confirmed in the soldering of both the terminals of the bypass capacitor 103 to the corresponding wiring circuits achieved by the above hot press, determination of whether the soldering has succeeded or not is difficult. Further, the depth of the through hole 102 in the core material 101, dimension of the bypass capacitor 103, or variation in the thickness of each of the high-melting point solders 104 formed on the surfaces of the both terminals of the bypass capacitor 103 is related to the success or failure of the soldering, making it difficult to manage the product quality.

In the multilayer lay-up process after the mounting of the bypass capacitor 103 in the printed wiring board, a condition of the hot press is restricted. That is, the hot press needs to be performed under a condition that the high melting-point solder 104 electrically connecting the bypass capacitor 103 buried in the core material 101 to the wiring circuit is not melted or thermally deformed.

For the above reasons, it is difficult to reduce manufacturing cost of the printed wiring board. For example, cost reduction of a multilayer wiring board in which the surface density of the via on the wiring board is expected to increase from the current value of, e.g., about 300,000/m² to e.g., 1,000,000/m² or more becomes difficult.

Next, an example of a multilayer wiring board in which a semiconductor bare chip is incorporated is illustrated in FIG. 8 (refer to, e.g., Jpn. Pat. Appln. Laid-Open Publication No. 2010-10714). In the printed wiring board of FIG. 8, an opening 113 is formed at a predetermined position of the core material 101, and a semiconductor bare chip 114 is inserted into the opening 113. The first wiring circuit 105 can be electrically conductive to the third wiring circuit 109 through the first conductive bump 108 penetrating the first interlayer dielectric layer 107 by the bump embedding method. Similarly, the second wiring circuit 106 can be electrically conductive to the fourth wiring circuit 112 through the second conductive bump 111 penetrating the second interlayer dielectric layer 110.

The semiconductor bare chip 114 is flip-chip connected to the fourth wiring circuit 112. In this case, an electrode pad (not illustrated) provided in the semiconductor bare chip 114 is connected to a wiring corresponding to the fourth wiring circuit 112 through a third conductive bump 115. The third conductive bump 115 is formed smaller than the abovementioned first conductive bump 108 and second conductive bump 111. The connection region between the semiconductor bare chip 114 and the fourth wiring circuit 112 is filled with an underfill resin 116. The fourth wiring circuit 112 can be electrically conductive to a fifth wiring circuit 119 through a fourth conductive bump 118 penetrating a third interlayer dielectric layer 117. Thus, in this case, a double-sided wiring board having the third interlayer dielectric layer 117 on the upper and lower surfaces of which the fourth wiring circuit 112 and fifth wiring circuit 119 are provided, respectively, and having the fourth conductive bump 118 sandwiched by the fourth wiring circuit 114 and fifth wiring circuit 119 is used.

In the printed wiring board incorporating a semiconductor bare chip, the first and second interlayer dielectric layers 107 and 110 soften as the prepreg materials in the hot press process are filled in a space around the semiconductor bare chip 114 by the fluidity obtained by heating and are then hardened and laminated integrally.

However, in such a printed wiring board, there is required a process of selectively etching (removing) the second interlayer dielectric layer 110 which is formed in the region where the semiconductor bare chip 114 is flip-chip connected to the fourth wiring circuit 112 for mounting. Further, it is required to prepare two types of conductive bumps having different sizes. This makes it difficult to simplify the manufacturing process of the printed wiring board, so that a reduction in the manufacturing cost of the printed wiring board is not easy.

Further, in the hot press process of the manufacturing process of the printed wiring board, the considerably wide space around the semiconductor bare chip 114 is filled with the first and second interlayer dielectric layers 107 and 110 as the prepreg materials. Accordingly, the thicknesses of the first and second interlayer dielectric layers 107 and 110 in the component mounting region are likely to be reduced. Thus, irregular products are likely to occur due to nonuniform thickness of the printed wiring board. The nonuniformity of the thickness of the printed wiring board becomes prominent as the component mounting density increases.

As described above, in existing printed wiring boards with built-in electronic component, including the above and other conventional printed wiring boards with built-in electronic component, the manufacturing method becomes complicated as the electronic component mounting density increases to reduce the productivity, thereby making it difficult to achieve a reduction in the cost of the printed wiring board.

According to the related art, increasing demand for the high-density mounting configuration and multilayer wiring configuration of the printed wiring board with built-in electronic component makes it difficult to achieve a cost reduction in manufacturing the same. The present invention has been made in view of the above situation, and an object thereof is to provide a printed wiring board with built-in component and its manufacturing method capable of easily realizing high-density mounting and multilayer wiring of the printed wiring board with built-in electronic component and capable of simplifying the manufacturing method itself.

### SUMMARY OF THE INVENTION

To achieve the above object, a printed wiring board with built-in component according to the present invention includes: a core dielectric layer having at least one opening penetrating from one main surface to the other main surface of the core dielectric layer; an electronic component brought into press contact with the side wall of the opening; first and second interlayer dielectric layers formed on the one main surface and the other main surface of the core dielectric layer configured to fill voids formed between the electronic component and the opening; a conductive layer laminated on the first or second interlayer dielectric layer; and a conductive member penetrating the first or second interlayer dielectric layer to be connected to an external terminal of the electronic component and the conductive layer.

A manufacturing method of a printed wiring board with built-in component according to the present invention includes: forming an opening penetrating a first main surface to a second main surface of a core material serving as an inner layer substrate; press-fitting an electronic component in the opening such that an external terminal of the electronic component is exposed facing the first or second main surface; laminating conductive plates each having an interlayer dielectric layer serving as an outer layer and a conductive bump on the first main surface and second main surface, respectively; integrating the laminated core material, interlayer dielectric layer, and conductive plate by heating and pressurization to connect the conductive bump penetrating the interlayer dielectric layer to the external terminal and filling voids formed between the opening and the electronic component with a part of the interlayer dielectric layer; and forming a wiring circuit by patterning the conductive plate.

### BRIEF DESCRIPTION OF THE DRAWINGS

FIG. 1A is a cross-sectional view illustrating an example of a printed wiring board with built-in component according to a first embodiment of the present invention;

FIG. 1B is a top view illustrating an example in which a built-in component is brought into press contact with an opening of a core material in the printed wiring board with built-in component according to the first embodiment;

FIGS. 2A to 2D are cross-sectional views illustrating an example of a manufacturing method of the printed wiring board with built-in component according to the first embodiment;

FIG. 3 is a cross-sectional view illustrating an example of the printed wiring board with built-in component according to a second embodiment of the present invention;

FIGS. 4A and 4B are plan views each illustrating an opening of the core material with which the built-in component is brought into press contact in the printed wiring board with built-in component according to the second embodiment;

FIGS. 5A and 5B are views illustrating an example of a manufacturing method of the printed wiring board with built-in component according to the second embodiment, in which FIG. 5A is a plan view, and FIG. 5B is a cross-sectional view taken along the Y-Y line of FIG. 5A;

FIGS. 6A and 6B are cross-sectional views illustrating manufacturing processes of the printed wiring board with built-in component continued from FIG. 5B;

FIG. 7 is a cross-sectional view illustrating a conventional printed wiring board with built-in component; and

FIG. 8 is a cross-sectional view illustrating another example of a conventional printed wiring board with built-in component.

### DESCRIPTION OF THE EMBODIMENTS

Embodiments of the present invention will be described below with reference to the accompanying drawings. Throughout the drawings, the same reference numerals are used to refer to the same or similar elements, and their description will be omitted partly. The drawings are schematic, and it should be noted that proportions between dimensions and the like are not actual.

### First Embodiment

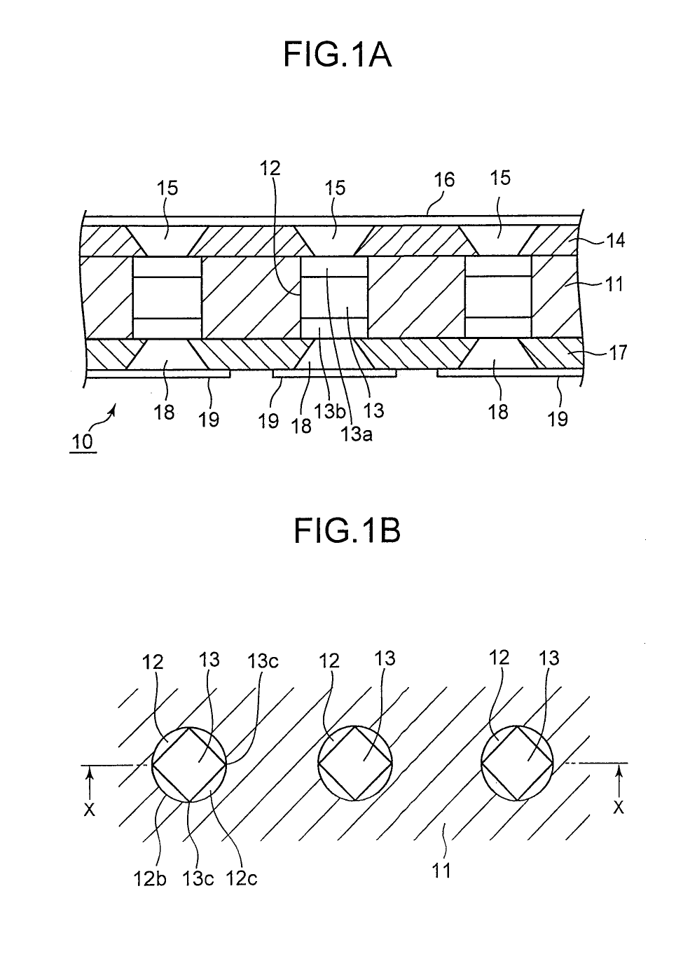

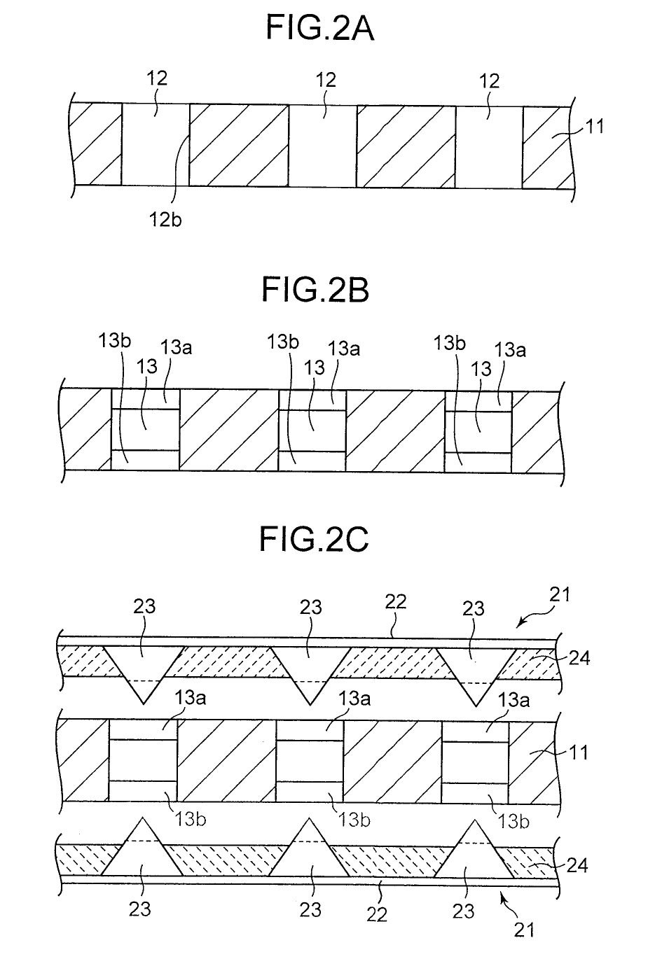

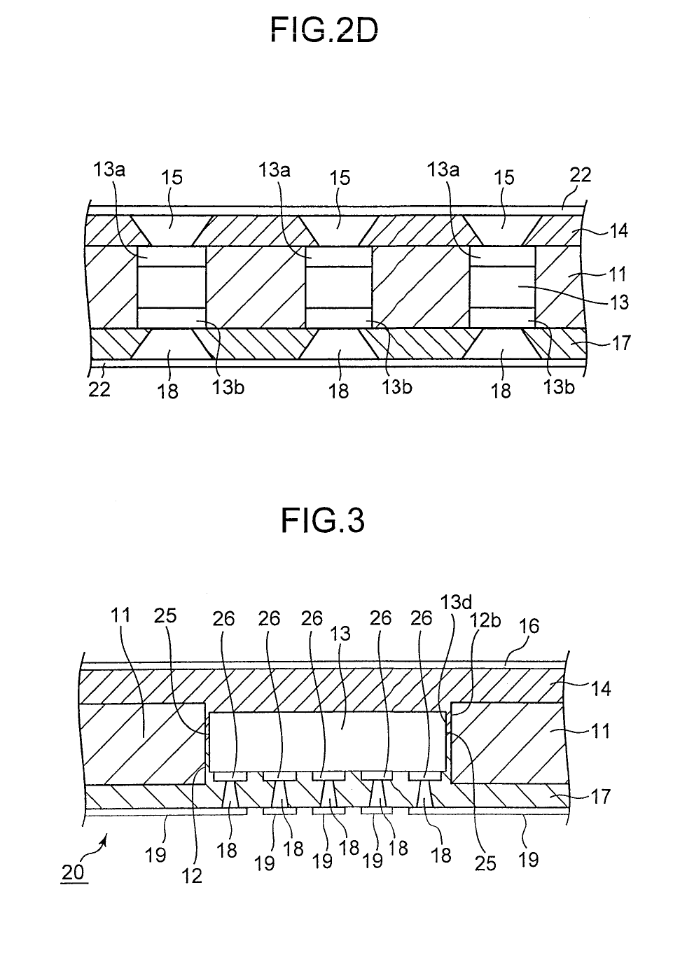

A printed wiring board with built-in component and its manufacturing method according to a first embodiment of the present invention will be described with reference to FIGS. 1A, 1B, and FIG. 2. As illustrated in FIG. 1A, in a printed wiring board with built-in component 10, an opening 12 is formed at a predetermined position of a core material 11 so as to penetrate the core material 11 from one main surface of the core material 11 to the other main surface, and an electronic component, i.e., an element 13 is brought into press contact with a part of the side wall of the opening 12. Both terminals 13a and 13b which are external terminals of a functional element 13 like a capacitor are exposed facing the front and rear surfaces serving as the one main and the other main surfaces of the core material 11. The functional element 13 is brought into press contact with the side wall of the opening 12 to be fixed in the opening 12.

A description will be added to the configuration in which the functional element 13 is brought into press contact with and fixed in the opening 12 with reference to FIG. 1B. As shown in FIG. 1B, in the case where the functional element 13 has a prismatic body and a planar shape of a rectangle, the opening 12 has a circular planar shape. The functional element 13 is inserted configured to be brought into press contact with a side wall 12b of the opening 12 at its corner portions (ridge lines) 13c. Spaces where the opening 12 and functional element 13 are not brought into press contact with each other become voids 12c.

A first interlayer dielectric layer 14 is formed, as the outer layer, on the one main surface with the core material 11 set as an inner layer substrate of a multilayer wiring board, and a first conductive bump 15 is formed as a conductive member at a predetermined position of the first interlayer dielectric layer 14. The terminal 13a of the functional element 13 is connected to the first conductive bump 15 so as to be electrically conductive to a first conductive layer 16 laminated on the first interlayer dielectric layer 14. Similarly, a second interlayer dielectric layer 17 is formed on the other main surface of the core material 11, and a second conductive bump 18 is formed as a conductive member at a predetermined position of the second interlayer dielectric layer 17. The terminal 13b of the functional element 13 is connected to the second conductive bump 18 so as to be electrically conductive to a second conductive layer 19 laminated on the second interlayer dielectric layer 17.

In the printed wiring board with built-in component 10, the first interlayer dielectric layer 14 and the second interlayer dielectric layer 17 have a function of filling the voids 12c formed between the opening 12 and the functional element 13 to thereby rigidly fix the functional element 13 in the opening 12.

For example, a glass-epoxy resin material which is a thermoset resin is suitably used as a material of the core material 11. There are other thermoset resin available, including a polyimide resin, a polyester resin, and a composite resin thereof. Further, a thermoplastic resin may be used. Examples of the thermoplastic resin include a liquid crystal polymer (LCP), a thermoplastic polyimide resin, and a composite resin thereof. At any rate, a glass cloth resin obtained by impregnating the thermoset resin or thermoplastic resin in a glass cloth is suitably used. Although details will be described later, in the case of the glass cloth resin, a small concavity and convexity is easily formed on the side wall of the opening 12 resulting from a use of the glass cloth when the opening 12 is formed by a punching process, which makes it easy to fixedly bring the functional element 13 into press contact with the opening 12.

The functional element 13 is an electronic component such as a capacitor, a resistor, a diode, a transistor, or an IC. Preferably, a single layer of, e.g., gold (Au), silver (Ag), nickel (Ni) or a composite layer of Ni/Au or Ni/Ag is plated on a metal material surface (such as a copper (Cu) material, aluminum (Al) material or stainless material) of the terminals 13a and 13b of the electronic component.

A glass epoxy resin which is a thermoset resin may be suitably used for the first interlayer dielectric layer 14 and second interlayer dielectric layer 17. Further, the thermoset resin or thermoplastic resin as described above may be suitably used.

The conductive bump 15 is formed of a metal material such as Ag, Cu, Au, or solder. The first conductive layer 16 and second conductive layer 17 are each a typical circuit wiring layer formed of Cu.

Next, an example of a manufacturing method of the printed wiring board with built-in component 10 will be described. As illustrated in FIG. 2A, the opening 12 is penetrated in the core material 11 having a thickness of e.g., about 50 μm to 1 mm by a punching process, a laser process, or drilling process. In the case where the functional element 13 is a capacitor having a prism shape, the opening 12 has a circular planar shape having a diameter of, e.g., 0.3 mm. The planar shape of the opening 12 may be an ellipse.

Then, as illustrated in FIG. 2B, the functional element 13 such as a capacitor is press-fitted and inserted in the opening 12 up to a predetermined depth position. As described in FIG. 1B, the corner portions of the functional element 13 is brought into press contact with the side wall of the opening 12 for temporarily fixation. Further, both the terminals 13a and 13b of the functional element 13 are exposed facing the front and rear surfaces of the core material 11. Thus, it is possible to freely fix the functional element 13 in the opening 12 without using the mounting configuration of the related art. FIG. 2B is a cross-sectional view taken along the X-X line of FIG. 1B.

In the case where the core material 11 is formed of the glass cloth resin, a small concavity and convexity is easily formed on the side wall of the opening 12, allowing stable press-fit of the functional element 13 in the opening 12, which makes it easy to fixedly bring the functional element 13 into press contact with the opening 12.

As illustrated in FIG. 2C, two so-called laminated plates 21 with conductive bump are prepared separately from the core material 11. Each laminated plate 21 with conductive bump is produced as follows. A metallic foil 22 having a thickness of, e.g., about 20 μm is prepared, and a silver-based conductive paste obtained by using an epoxy resin as a binder is screen-printed on a predetermined position of the metallic foil 22 through a metal mask. Thereafter, the conductive paste is dried and cured to form cone-shaped conductive bumps 23. The height of each conductive bump 23 is set to about 100 μm. Then, an epoxy resin glass cloth prepreg 24 having a thickness of about 80 μm is laminated on the metallic foil 21 from the conductive bump 23 side by means of a press machine. At this time, the head portions of the cone-shaped conductive bumps 23 penetrate the prepreg 24 to thereby form the laminated plate 21 with conductive bump.

Further, as illustrated in FIG. 2C, the conductive bumps 23 of the two laminated plates 21 with conductive bump are positioned corresponding to the terminals of the respective functional elements 13. Thereafter, the two laminated plates 21 with conductive bump are laminated on the front and rear surfaces of the core material 11 followed by a hot press process. In the hot press process, atmosphere gas is in a decompressed state, and heating temperature at that time is, e.g., 180° C. to 230° C. The pressurization is carried out at, e.g., 30 to 100 kgf/cm². In the heating and pressurization process, the prepreg 24 obtains fluidity to fill the voids formed between the opening 12 and functional element 13 followed by curing, to allow the functional element 13 to be fixed in the opening 12.

In this manner, as illustrated in FIG. 2D, the first interlayer dielectric layer 14 is formed as the outer layer on the front surface side of the core material 11 which is the inner layer substrate, and the second interlayer dielectric layer 17 is formed as the outer layer on the rear surface side of the core material 11, whereby a multilayer structure is achieved. The conductive bumps 23 are crushed at their distal ends to be the first and second conductive bumps 15 and 18 electrically connected to the both terminals 13a and 13b.

The cone-shaped conductive bumps 23 may each have a shape obtained by cutting off the distal end. For example, the conductive bumps 23 illustrated in FIG. 2C are cut off at the broken lines.

Then, the resultant structure is immersed in chemical etching solution composed of copper chloride water solution or aqueous ferric chloride, and the metallic foil 22 is selectively etched by using an etching resist (not illustrated) as an etching mask to be patterned. In this manner, as illustrated in FIG. 1A, the first conductive layer 16 is formed on the first interlayer dielectric layer 14, and the second conductive layer 19 is formed on the second interlayer dielectric layer 17, whereby the printed wiring board 10 with built-in component is obtained. The printed wiring board 10 with built-in component is preferably used as a rigid wiring board but may be used as a Flexible Printed Circuit (FPC).

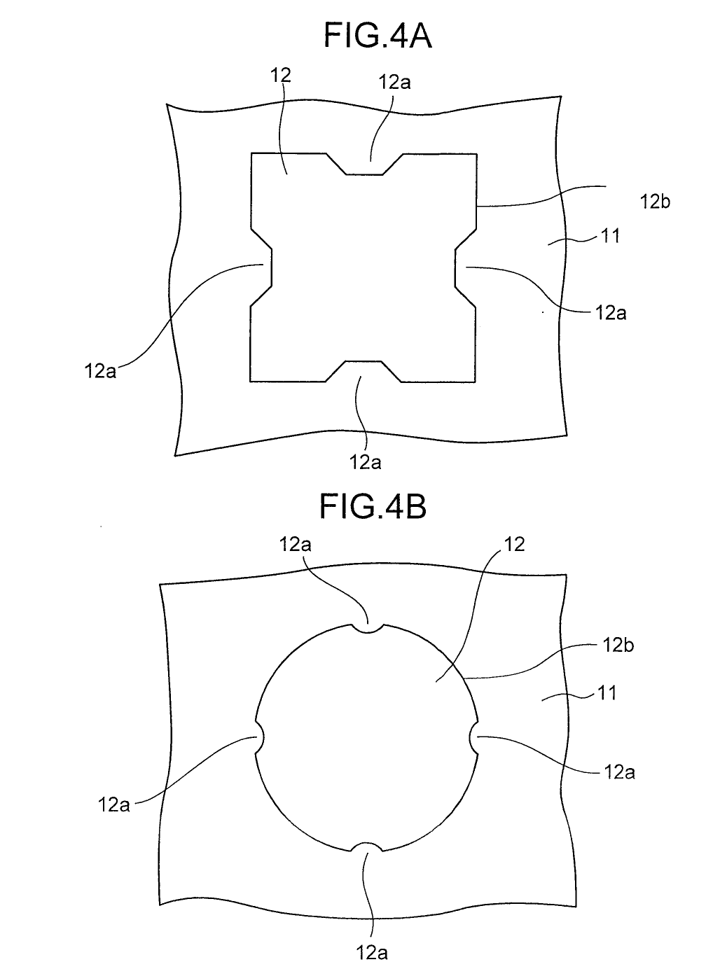

In the present embodiment, the planar shape of the opening 12 is formed so as to have a planar shape corresponding to the shape of the functional element 13. For example, in the case where the functional element 13 has a columnar shape, the opening 12 is formed so as to have a rectangular or polygonal planar shape. The opening 12 and functional element 13 may have the same planar shape. Further, the opening 12 may have planar shapes as illustrated in FIGS. 4A and 4B.

Although not illustrated, in the printed wiring board 10 with built-in component, wiring circuits may be formed respectively on both surfaces of the core material 11 in the areas other than those in which the terminals of the functional elements 13 are exposed. In this case, a manufacturing method may be employed in which the prepreg 24 is laminated on the front and rear surfaces of the core material 11 as in the case of the bump embedding method and, after that, the metallic foil 22 on which the cone-shaped conductive bumps 23 are formed is positioned, followed by hot press.

In the printed wiring board with built-in component according to the present embodiment, the functional element 13 is inserted so as to be brought into press contact with the side wall of the opening 12 formed in the inner layer substrate of the wiring board and fixed in the opening 12. Then, in the multilayer configuration obtained after lamination of the outer layer, the terminals 13a and 13b of the inserted functional element 13 are connected respectively to the conductive bumps 15 and 18 each serving as a via connected to the outer layer circuit wiring. The voids formed at this time between the opening 12 and the functional element 13 are filled with a part of the interlayer dielectric layers 14 and 17 each serving as the outer layer. Thus, the printed wiring board with built-in component according to the present embodiment can realize high-density mounting of the electronic component such as the functional element 13 and multilayer wiring more easily.

In addition, the mounting process of the functional element 13 performed in the related art becomes unnecessary, allowing simplification of the manufacturing method of the printed wiring board with built-in component. Further, in the hot press between the inner layer substrate and interlayer dielectric layer serving as the outer layer, alignment between the terminals 13a and 13b of the functional element 13 to be built-in and conductive bumps 15 and 18 can be achieved correctly, thereby stably establishing electrical connection between them. Further, the uniformity of the thickness of the printed wiring board with built-in component is improved. As a result, quality management in the manufacturing process can be easily achieved.

Thus, even in the configuration in which the high-density mounting and multilayer wiring of the printed wiring board with built-in component have been achieved, an increase in productivity as well as a reduction in manufacturing cost can easily be realized. As a result, it is possible to provide a low-cost printed wiring board with built-in component.

### Second Embodiment

Next, a printed wiring board with built-in component and its manufacturing method according to a second embodiment of the present invention will be described with reference to FIGS. 3 to 6. In this embodiment, an active element having a large diameter, such as an IC, is easily brought into press contact with and fixed in the opening. This is a main different point from the first embodiment. Hereinafter, the different point will be mainly described.

As illustrated in FIGS. 3, 4A, and 4B, in a printed wiring board 20 with built-in component, the opening 12 is formed at a predetermined position of the core material 11 so as to penetrate the core material 11 from one surface thereof to the other surface, and the functional element 13 is fitted so as to be brought into press contact with protrusion portions 12a formed in the side wall of the opening 12. As illustrated in FIG. 4A, in the opening 12 having a rectangular planar shape, the protrusion portions 12a each protrude inside from the side of the opening 12 in a trapezoidal shape. The opening 12 may have a shape as illustrated in FIG. 1.

The protruding structure may be formed so as to extend from the front surface of the core material 11 to the rear surface thereof or may be formed at a part of the side wall of the opening 12. The height of the protrusion portion 12a from the side wall is appropriately determined depending on the hardness of the core material 11 and is, for example, about 1 μm. This height may be changed so as to increase from the first main surface of the core material 11 toward the second main surface. Further, the protrusion portion 12a is appropriately formed depending on the planar shape of the opening 12. In the example of FIG. 4B, arc-like protrusion portions 12a are formed on the side wall of the opening 12.

In the regions other than those in which the protrusion portions 12a are formed, gaps 25 are formed between the opening 12 and the functional element 13. The functional element 13 is e.g., an IC semiconductor bare chip, and a required number of electrode pads 26 each serving as an external terminal are provided on the surface of the IC chip mounted in a flip chip configuration.

The first interlayer dielectric layer 14 having the first conductive layer 16 is formed, as the outer layer, on the one main surface with the core material 11 set as an inner layer substrate of the multilayer wiring board. Further, the second interlayer dielectric layer 17 is formed on the second main surface of the core material 11, and the second conductive bumps 18 are formed as a conductive member at predetermined positions of the second interlayer dielectric layer 17. The electrode pads 26 of the functional element 13 are connected to the second conductive bumps 18 so as to be electrically conductive to the second conductive layers 19 laminated on the second interlayer dielectric layer 17.

The first interlayer dielectric layer 14 and second interlayer dielectric layer 17 fill spaces including the gaps 25 formed between the opening 12 and functional element 13 from above and below to thereby rigidly fix the functional element 13 in the opening 12.

Preferably, a single layer of, e.g., Au, Ag, Ni or a composite layer of Ni/Au or Ni/Ag is plated on the surface of the electrode pad 26 of the functional element 13. Alternatively, the electrode pad 26 may have a conductive bump structure like, e.g., a solder bump. Other configurations including the constitute materials thereof are the same as those of the first embodiment.

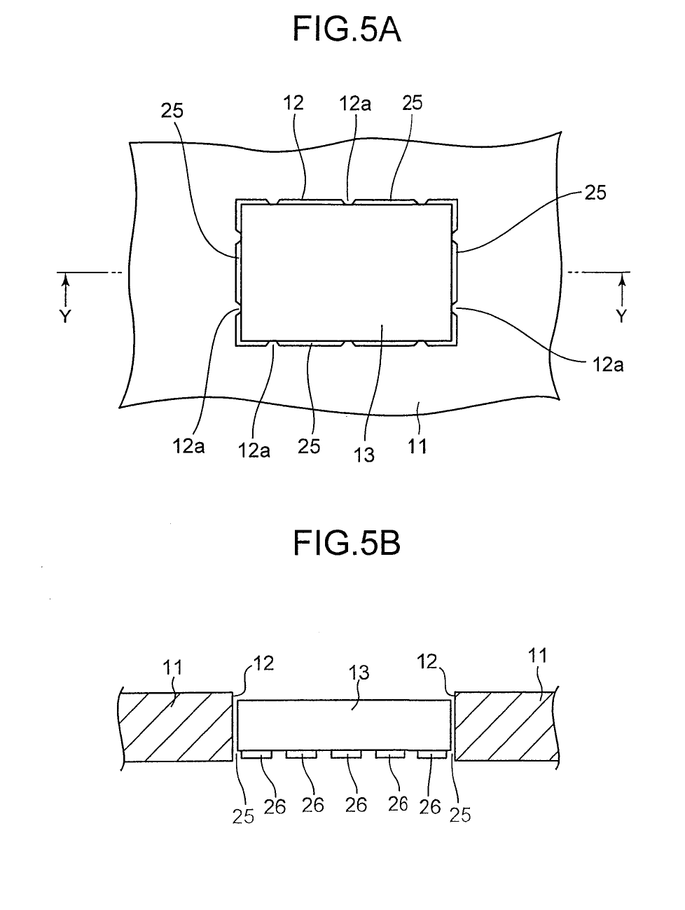

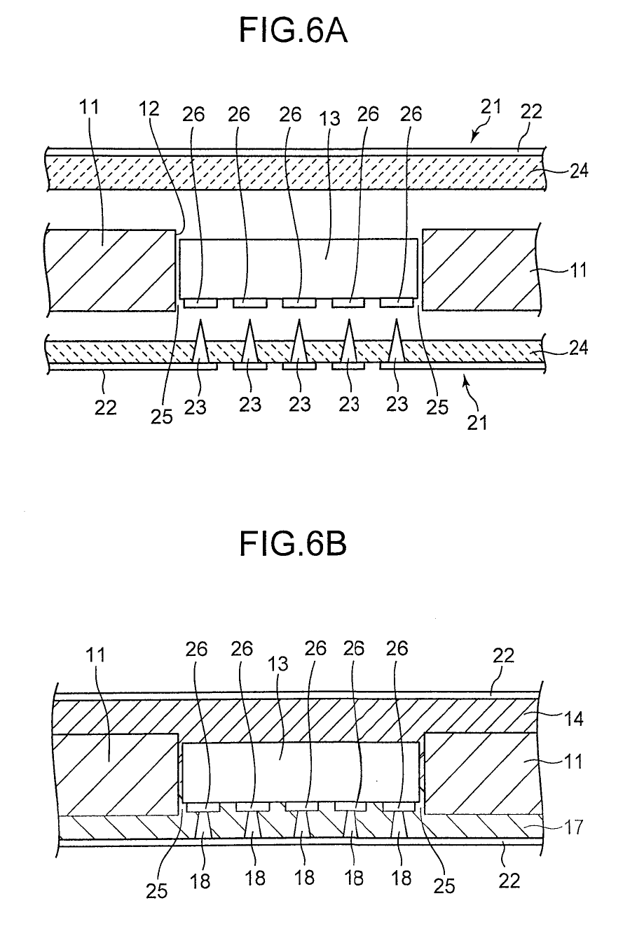

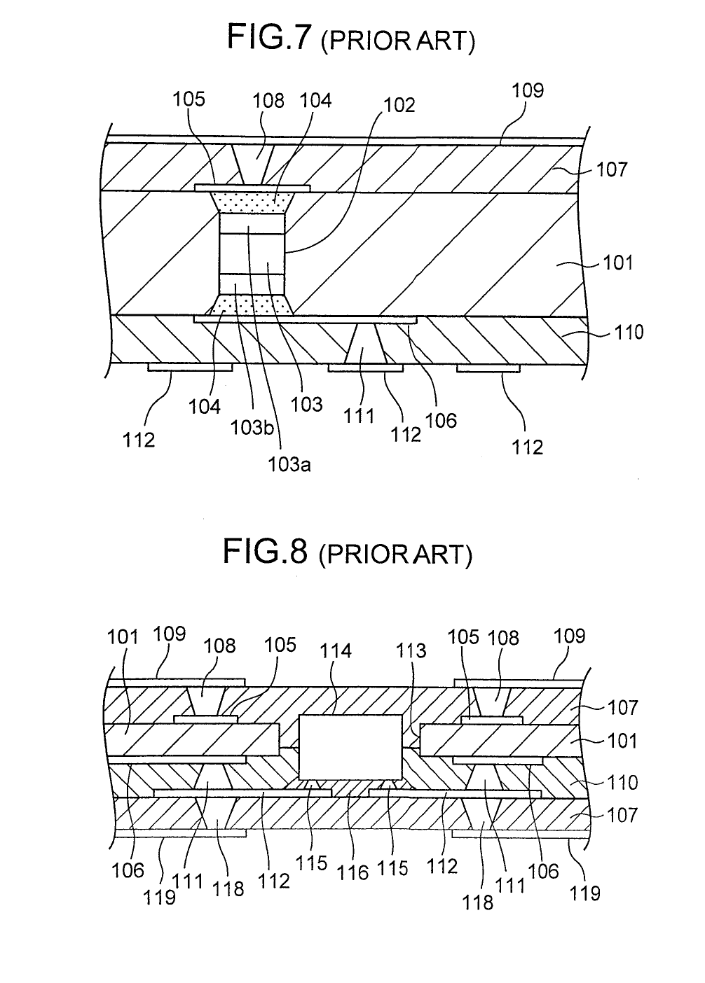

Next, an example of a manufacturing method of the printed wiring board with built-in component according to the second embodiment will be described with reference to FIGS. 5 and 6. In a process of forming the opening 12 in the core material 11, the core material 11 is punched by a punch having a surface groove corresponding to the protrusion portion 12a. In this manner, as illustrated in FIGS. 5A and 5B, the opening 12 having the protrusion portions 12a at predetermined positions of the core material 11 is formed.

Subsequently, the functional element 13 such as an IC is press-fit inserted into the opening 12 in a face-down manner. At this time, the functional element 13 is brought into press contact with the protrusion portions 12a of the opening 12. In the case where the area of the IC chip is as large as 10 mm×10 mm block, the IC (functional element 13) is press-fit to a predetermined depth position with a predetermined pressing force with the rear surface of the IC chip held by using a head having a vacuum contact mechanism.

Then, as illustrated in FIG. 6A, the conductive bumps 23 of the laminated plates 21 with conductive bump formed in the same manner as in the first embodiment are positioned corresponding to the electrode pads 26 of the functional element 13. Thereafter, as in the case of the first embodiment, the two laminated plates 21 with conductive bump are laminated on the front and rear surfaces of the core material 11 followed by the hot press process. In the hot press process, the prepreg 24 obtains fluidity to fill the space including the gaps 25 formed between the opening 12 and functional element 13 followed by curing, to allow the functional element 13 to be fixed in the opening 12.

In this manner, as illustrated in FIG. 6B, the first interlayer dielectric layer 14 and second interlayer dielectric layer 17 are formed as the outer layers on the front surface and rear surface sides of the core material 11, respectively, whereby a multilayer structure is achieved. The conductive bumps 23 are crushed at their distal ends to be the second conductive bumps 18 electrically connected to the electrode pads 26. Although the first conductive bumps 15 are not illustrated in the first interlayer dielectric layer 14, they may be formed around another functional element built in an area not seen in the drawing of FIG. 6B.

The metallic foil 22 is patterned as described in the first embodiment. In this manner, as illustrated in FIG. 3, the first conductive layer 16 is formed on the first interlayer dielectric layer 14, and similarly, the second conductive layer 19 is formed on the second interlayer dielectric layer 17, whereby the printed wiring board 20 with built-in component is obtained.

The second embodiment can provide the same effects as those of the first embodiment, and the high-density mounting and multilayer wiring of the printed wiring board with built-in component, as well as, a cost reduction of the printed wiring board with built-in component can be easily achieved. Further, in the second embodiment, the functional element 13 is partly brought into press contact with the protrusion portions 12a formed in the side wall of the opening 12, so that even the functional element 13 having a large planar area can be press-fitted stably with good reproducibility. Therefore, even in the case where the functional element 13 is an IC chip having a size as large as 10 mm×10 mm block, stable production of the printed wiring board with built-in component can be easily achieved.

Although embodiments of the present invention have thus been described, the present invention is by no means limited to the embodiments described above. Various modifications and changes may be made in a concrete embodiment without departing from the technical concept and technical scope of the invention.

As a substitute for the conductive bump as described in the above embodiments, in other multilayer lay-up processes, a configuration may be employed in which a via between wiring circuits used in the buildup of the multilayer is connected to the terminal of the functional element 13.

Although the printed wiring board incorporates the functional element 13 as the electronic component in the above embodiments, the present invention may be applied to a case where other electronic component or an electric component is incorporated in the printed wiring board.

What is claimed is:

1. A printed wiring board with built-in component, comprising:
a core dielectric layer having at least one opening penetrating from one main surface to the other main surface of the core dielectric layer;
an electronic component brought into press contact with the side wall of the opening;
first and second interlayer dielectric layers formed on the one main surface and the other main surface of the core dielectric layer configured to fill voids formed between the electronic component and the opening;
a conductive layer laminated on the first or second interlayer dielectric layer; and
a conductive member penetrating the first or second interlayer dielectric layer to be connected to an external terminal of the electronic component and the conductive layer.

2. The printed wiring board with built-in component according to claim 1, wherein
a part of the electronic component is brought into press contact with the side wall of the opening.

3. The printed wiring board with built-in component according to claim 1, wherein
the electronic component is brought into press contact with a protrusion portion formed in the side wall of the opening.

4. The printed wiring board with built-in component according to claim 1, wherein
the core dielectric layer contains glass fiber.

5. A manufacturing method of a printed wiring board with built-in component, comprising:
forming an opening penetrating a first main surface to a second main surface of a core material serving as an inner layer substrate;
press-fitting an electronic component in the opening such that an external terminal of the electronic component is exposed facing the first or second main surface;
laminating conductive plates each having an interlayer dielectric layer serving as an outer layer and a conductive bump on the first main surface and second main surface, respectively;
integrating the laminated core material, interlayer dielectric layer, and conductive plate by heating and pressurization to connect the conductive bump penetrating the interlayer dielectric layer to the external terminal and filling voids formed between the opening and the electronic component with a part of the interlayer dielectric layer; and
forming a wiring circuit by patterning the conductive plate.

6. The printed wiring board with built-in component according to claim 2, wherein
the electronic component is brought into press contact with a protrusion portion formed in the side wall of the opening.

7. The printed wiring board with built-in component according to claim 2, wherein
the core dielectric layer contains glass fiber.

8. The printed wiring board with built-in component according to claim 3, wherein
the core dielectric layer contains glass fiber.
